(19) United States
(12) Patent Application Publication
(10) Pub. No.: US 2012/0240971 A1
(43) Pub. Date: Sep. 27, 2012

(54) PROCESS FOR FORMING FLEXIBLE SUBSTRATES HAVING PATTERNED CONTACT AREAS

(75) Inventors: John Telle, Albuquerque, NM (US); William Bottenberg, Boulder Creek, CA (US); Brian J. Murphy, Albuquerque, MN (US); David H. Meakin, Albuquerque, NM (US)

(73) Assignee: Applied Material, Inc., Santa Clara, CA (US)

(21) Appl. No.: 13/420,178

(22) Filed: Mar. 14, 2012

Related U.S. Application Data
(60) Provisional application No. 61/486,719, filed on May 16, 2011.
(60) Provisional application No. 61/454,382, filed on Mar. 18, 2011.

(51) Int. Cl. H01L 31/05; H05K 3/02

(52) U.S. Cl. 136/244; 29/847

(57) ABSTRACT

Embodiments of the invention generally include a method of forming a low cost flexible substrate having one or more conductive elements that are used to form a low resistance current carrying path used to interconnect a plurality of solar cell devices disposed in a photovoltaic module. A surface of the one or more conductive elements will generally comprise a plurality of patterned electrical contact regions that are used to form part of the electrical circuit that interconnects the plurality of solar cell devices. The plurality of electrical contact points form an electrical circuit that has a lower series resistance versus conventional designs. Embodiments may also include a method and apparatus that form the electrical contact regions on an inexpensive conductive material before electrically connecting the anode or cathode regions of a formed solar cell to the conductive material.

### CROSS-REFERENCE TO RELATED APPLICATIONS

This application claims benefit of U.S. Provisional Patent Application Ser. No. 61/486,719 [Atty. Dkt. No. APPM/16283L], filed May 16, 2011, and U.S. Provisional Patent Application Ser. No. 61/454,382 [Atty. Dkt. No. APPM/16122L], filed Mar. 18, 2011, which are both herein incorporated by reference.

### BACKGROUND OF THE INVENTION

1. Field of the Invention

Embodiments of the invention generally relate to a flexible substrate used to interconnect solar cells in a photovoltaic module, and a method of forming the same.

2. Description of the Related Art

Solar cells are photovoltaic devices that convert sunlight into electrical power. Each solar cell generates a specific amount of electric power and is typically tiled into an array of interconnected solar cells that are sized to deliver a desired amount of generated electrical power. The most common solar cell base material is silicon, which is in the form of single crystal, multicrystalline or polycrystalline substrates. Because the amortized cost of forming silicon-based solar cells to generate electricity is higher than the cost of generating electricity using traditional methods, there has been an effort to reduce the cost to form solar cells and the photovoltaic modules in which they are interconnected and housed.

FIG. 1 illustrates a bottom view of a conventional photovoltaic module 100 having an array of interconnected solar cells 101 disposed over a top surface of a backsheet 103 (e.g., glass substrate), as viewed through the bottom surface of the backsheet 103. For clarity reasons, the backsheet 103 illustrated in FIG. 1 is schematically shown as being transparent to allow one to view the components in the photovoltaic module 100. The solar cells 101 in the photovoltaic module 100 can be back-contact type solar cells in which light received on a front surface of a solar cell 101, which is the opposite side of the view shown in FIG. 1, is converted into electrical energy. The solar cells 101 in the solar cell array 101A are interconnected in a desired way by use of conducting strips 105A and 105C. In one configuration, the solar cells 101 in the solar cell array 101A are connected in series, such that the generated voltage of all the connected solar cells will add and the generated current remains relatively constant. In this configuration, the n-type and p-type regions formed in each interconnected solar cell are separately connected to regions formed in adjacent solar cells that have an opposing dopant type by use of the conducting strips 105A. To form the series connected circuit, it is common for the start or end of each row of solar cells 101 in the solar cell array 101A to be connected to the start or end of an adjacent row by interconnects 106, and the start and end of the solar cell array 101A are connected to an external load “L” by use of the interconnects 107. Typical external components, or external loads “L”, may include an electrical power grid, satellites, electronic devices or other similar power requiring units.

The typical fabrication sequence of photovoltaic modules using silicon solar cells includes the formation of a solar cell circuit, assembly of a layered structure (glass, polymer, solar cell circuit, electrically conductive adhesive, polymer, backsheet), and then encapsulation of the solar cells and electrical connections by lamination of the layered structure and solar cell circuit together. When completely formed, the photovoltaic modules generally contain an array of solar cells that are electrically interconnected by use of the conducting strips 105A, 105B formed in the solar cell circuit. FIG. 1B is a schematic representation of a conventional electrical circuit 150 that is formed by interconnecting a plurality of solar cells, for example three solar cells S₁-S₃, in series to an external load “L”. As illustrated in FIG. 1B, the series connected electrical circuit 150 includes a plurality of solar cells S₁-S₃ that are connected to conducting strips 105A by use of an electrically conductive material 110, and to the load “L” by use of two interconnects 107. The ability of the formed photovoltaic module 100 to efficiently deliver the electrical power generated by the solar cells S₁-S₃ to the external load “L” depends on the resistance of the formed electrical circuit 150. In general, the resistance of the formed electrical circuit 150 is the sum of all of the series resistances in the electrical circuit 150. For example, in the electrical circuit 150 shown in FIG. 1B the total resistance will include the sum of the resistances of all of the electrically conductive materials 110 (e.g., 8×R_{IM}), the sum of all of the conducting strip 105A resistances (e.g., 4×R_{CE}), the sum of all of the interconnect 107 resistances (e.g., 2×R_{EC}), and the sum of all of the contact resistances (e.g., R_{C1}+R_{C2}+ . . . +R_{C8}) formed between the electrically conductive materials 110 and the conducting strips 105A. One will note that the contact resistance element created between each of the electrically conductive materials 110 and the solar cell 101 connection points, and the electrically conductive materials 110 and the interconnects 107 is assumed to be negligible to help simplify the discussion.

The conductive strips 105A in the solar cell circuit generally include sheets of patterned copper material having a desired shape to allow the series, or parallel, interconnection of the solar cells disposed in the layered structure formed in the photovoltaic module. Since copper is expensive compared to other materials, there has been an interest in using aluminum in place of copper. However, aluminum forms a thick stable oxide on its surface when exposed to the atmosphere, which prevents a good electrical contact from being formed between the electrically conductive material 110 (e.g., silver epoxy material), used to connect the anode or cathode contact regions of each solar cell, and the aluminum material. The high contact resistance formed at the interface of each of the connection points formed between the aluminum and a conductive material 110 (e.g., R_{C1}−R_{C8} in FIG. 1B) add for each series connected solar cell, which can significantly increase the overall resistance of the formed interconnect circuit, and thus reduce the ability of the array of solar cells to efficiently deliver their generated power to the external load (e.g., power grid, etc.). One will appreciate that each individual contact resistance in the electrical circuit 150, for example contact resistance R_{C2}, is actually the sum of all of the parallel connected contact resistances of all of the contact regions, such as all of the p-type regions, formed on a single solar cell device (e.g., solar cell S₁). However, the overall efficiency of each solar cell device is dependent on the ability of each of the parallel electrical connections to deliver the generated current in its local area of the solar cell substrate to the electrical circuit 150. Therefore, a poor connection at a parallel electrical connection point will inhibit the flow of current from that local region of the solar substrate, and thus reduce the efficiency of the solar cell device and the series connected array of solar cell devices.

Therefore, there is a need for a method and apparatus for forming an electrical circuit that interconnects a plurality of solar cells, which includes an inexpensive material, such as aluminum, and has a similar electrical characteristic as a circuit containing copper interconnecting elements.

### SUMMARY OF THE INVENTION

Embodiments of the invention generally include a method of forming a low cost flexible substrate that includes one or more conductive elements that are used to form part of an electrical circuit that interconnects a plurality of solar cell devices disposed in a photovoltaic module. A surface of each of the one or more conductive elements will generally comprise a plurality of patterned electrical contact regions, or electrical contact points, that are used to form part of the electrical circuit that interconnects the plurality of solar cell devices, and the solar cell devices to an external load. Due to the method of forming the electrical contact regions and the electrical properties of the materials found in the electrical contact regions on the one or more conductive elements the formed electrical circuit will have a lower series resistance versus an electrical circuit that has one or more conductive elements that do not have the electrical contact regions formed thereon. In one configuration, the plurality of electrical contact regions are formed on a surface of the one or more conductive elements that comprise a material that readily forms a thick oxide layer thereon, or has a surface that has received minimal surface preparation prior to use in the photovoltaic module. The methods disclosed herein also generally include a method and apparatus used to rapidly and reliably form the electrical contact regions on an inexpensive conductive material, such as aluminum, before electrically connecting the anode or cathode regions of a formed solar cell to the conductive material.

Embodiments of the invention also may generally provide a method of forming a flexible substrate used to interconnect photovoltaic devices, comprising bonding a conductive element to a flexible backsheet, wherein the conductive element comprises a metal layer that has an element surface, removing portions of the conductive element to form two or more conductive element regions that are electrically isolated from each other, and forming plurality of a contact regions on the surface of the conductive element, comprising disposing a metal sheet over the element surface, and joining a portion of the metal sheet to the element surface of the metal layer.

Embodiments of the invention also provide a substrate for interconnecting photovoltaic devices, comprising a conductive element comprising aluminum that is disposed over a surface of a flexible backsheet, wherein the conductive element comprises a plurality of connection element regions that are electrically separated from each other, and a plurality of a contact regions disposed on a surface of each of the connection element regions, wherein the contact regions comprise a conductive material that is not aluminum.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a bottom view illustrating a conventional photovoltaic module.

FIG. 1B is schematic representation of a conventional electrical circuit used to interconnect a plurality of solar cells.

FIG. 2 is a schematic cross-sectional view that illustrates a solar cell module according to one embodiment of the invention.

FIG. 3 is a plan view illustrating a photovoltaic module according to one embodiment of the invention.

FIGS. 4 and 5 are schematic illustrations of a shaped metal foil which may be formed according to embodiments of the invention.

FIG. 6A is a schematic cross-sectional view that illustrates a connection point and schematic electrical circuit formed between a solar cell and a conductive element.

FIG. 6B is a schematic cross-sectional view that illustrates a connection point and schematic electrical circuit formed between a solar cell and a conductive element according to one embodiment of the invention.

FIG. 7 is a schematic illustration of a system for forming flexible substrates according to one embodiment of the invention.

FIG. 8 is a process flow diagram of a method of forming at least a part of a photovoltaic module using the system shown in FIG. 7 according to one embodiment of the invention.

FIG. 9 is a schematic illustration of a system for forming flexible substrates according to one embodiment of the invention.

FIG. 10 is a process flow diagram of a method of forming at least a part of a photovoltaic module using the system shown in FIG. 9 according to one embodiment of the invention.

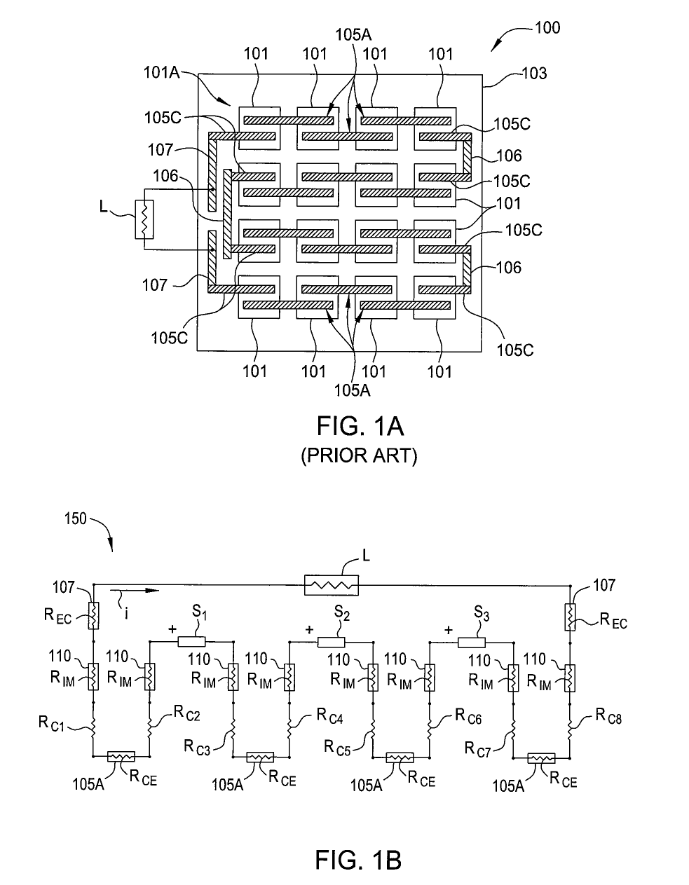

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

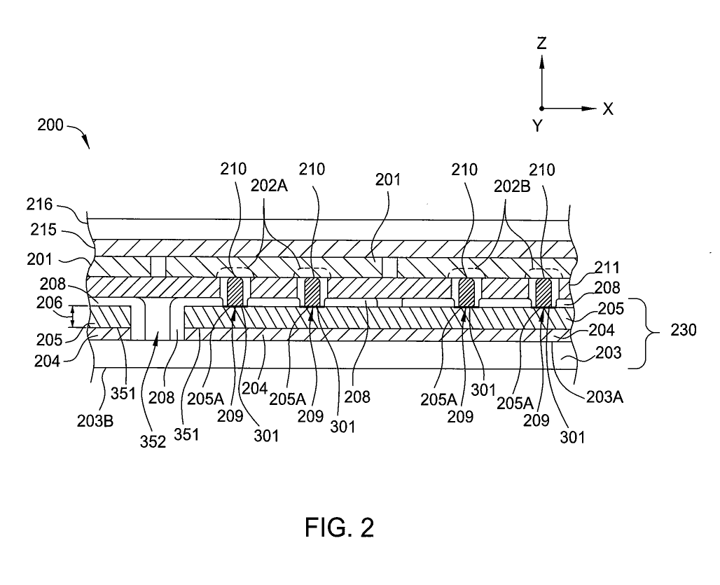

Embodiments of the invention generally include a method of forming a low cost flexible substrate having one or more conductive elements that are used to form a low resistance current carrying path that is used to interconnect a plurality of solar cell devices disposed in a photovoltaic module. A surface of each of the one or more conductive elements will generally comprise a plurality of patterned electrical contact regions, or electrical contact points, that are used to form part of the electrical circuit that interconnects the plurality of solar cell devices and the solar cell devices to an external load. The plurality of formed electrical contact points allow the formed electrical circuit to have a lower series resistance versus an electrical circuit that has one or more conductive elements that do not have the electrical contact regions formed therein. In one embodiment, the plurality of discrete electrical contact regions, such as the patterned contact regions 301 shown in FIGS. 2-7, are formed on a surface of the one or more conductive elements that comprise a material that readily forms a thick oxide layer thereon, or has a surface that has received minimal surface preparation prior to use in the photovoltaic module. The methods disclosed herein also generally include a method and apparatus used to rapidly and reliably form the electrical contact regions on an inexpensive conductive material, such as aluminum, before electrically connecting the anode or cathode regions of a formed solar cell to the conductive material. Solar cell structures that may benefit from the invention disclosed herein include solar cells that have both positive and negative electrical contacts formed on the rear surface of the solar cell device. The term “flexible substrate” as used herein generally refers to a multi-layered substrate suitable for use in roll-to-roll processing systems.

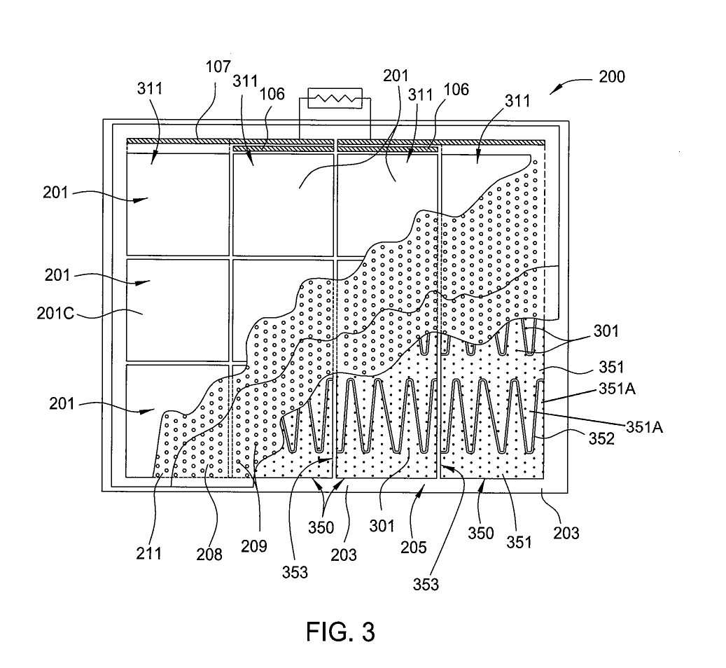

FIG. 2 illustrates a side cross-sectional view of a formed photovoltaic module 200 that may include one or more embodiments of the invention described herein. FIG. 3 is a partial cross-sectional of the photovoltaic module 200 as viewed from light receiving side of the photovoltaic module 200, which illustrates an array of interconnected solar cells 201 disposed over a top surface of a backsheet assembly 230 (FIG. 2). In one configuration, as illustrated in FIG. 2, the photovoltaic module 200 includes a backsheet assembly 230, an interlayer dielectric layer (ILD) material 208, a module encapsulant material 211, a patterned conductive interconnect material 210, a plurality of solar cells 201, a front encapsulant layer 215 and a glass substrate 216. In one configuration, the backsheet assembly 230 comprises a backsheet 203, an adhesive material 204, a conductive element 205 and a plurality of patterned contact regions 301 formed on the conductive element 205. The configuration of the photovoltaic module 200 discussed below is provided as an example of a device that may benefit from one or more of the embodiments disclosed herein and is not intended to be limiting as to the scope of the invention(s) described herein, since the orientation, position and number of components disposed between the glass substrate 216 and the backsheet 203 can be adjusted without deviating from the basic scope of the invention disclosed herein. The solar cells 201 disposed in the photovoltaic module 200 may be formed from substrates containing materials, such as single crystal silicon, multi-crystalline silicon, polycrystalline silicon, germanium (Ge), gallium arsenide (GaAs), as well as heterojunction cells, such as GaInP/GaAs/Ge, ZnSe/GaAs/Ge or other similar substrate materials that are used to convert sunlight to electrical power.

The conductive element 205, as illustrated in FIG. 3, may comprise one or more conductive sections 350 (e.g., three of the four sections are shown in FIG. 3) that are coupled or bonded to the backsheet 203 and used to interconnect the solar cells 201. The process of bonding the conductive element 205 to the backsheet 203 may include applying pressure to the backsheet 203, conductive element 205 and the adhesive material 204 disposed between the backsheet 203 and the conductive element 205, and then let the adhesive material 204 cure. The adhesive material 204 can be a low temperature curable adhesive (e.g., <180° C.) that doesn't significantly out-gas. The adhesive material 204 can be a pressure sensitive adhesive, such as FLEXMARK® PM 500 (clear) available from Flexcon of Spencer, Mass., and may be applied to a thickness of about 5 microns. The adhesive material 204 can be applied to the surface 203A of the backsheet 203 or conductive element 205 using screen printing, stenciling, ink jet printing, rubber stamping or other useful application method.

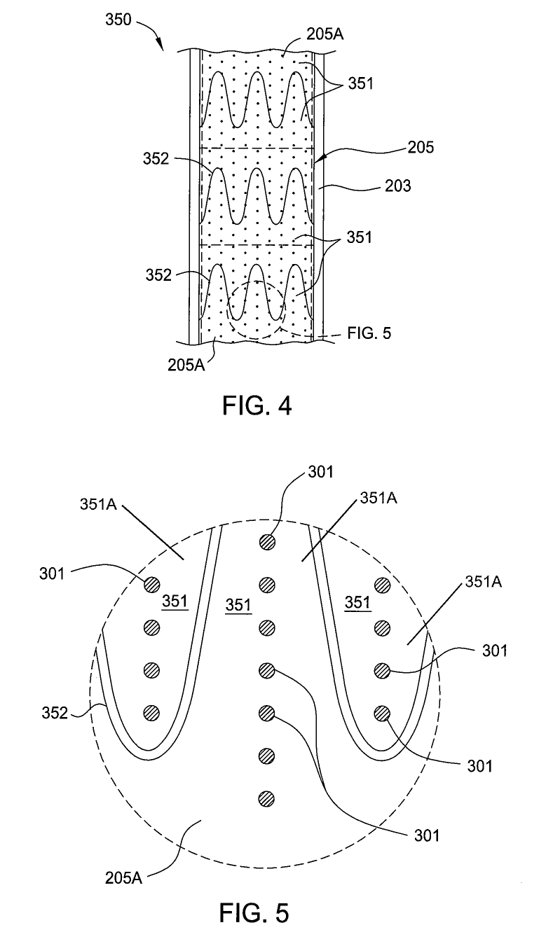

The one or more conductive sections 350 generally comprise a plurality of connection element regions 351 that are separated from each other by separation grooves 352 and 353. When used in a photovoltaic module 200 that has a plurality of solar cells that are connected in series, each of the connection element regions 351 are used to connect regions formed in adjacent solar cells that have an opposing dopant type. In one configuration, each of the conductive sections 350 is formed in a separate formation process and then positioned in a spaced apart relationship on the backsheet 203 so that the separation groove 353 electrically separates each conductive section 350. In one example, each conductive section 350 is used to interconnect a group of solar cells 201, such as the four solar cells 201 disposed in one of the four solar cell columns 311 (FIG. 3) in the photovoltaic module 200. In some configurations, only a single conductive section 350 is used to interconnect rows (horizontal groups) and columns (vertical groups) of solar cells in the array of solar cells disposed in the photovoltaic module 200. The separation grooves 352 and 353 are formed by removing portions of the conductive element 205, for example, by use of an automated punch press, abrasive saw, laser scribing device or other similar cutting technique. The separation grooves 352 and 353 may be formed before or after the conductive element 205 is affixed to the backsheet 203, but are typically formed after the conductive element 205 is affixed to the surface 203A of the backsheet 203. The conductive sections 350 generally comprise a plurality of connection element regions 351, or conductive regions, that are separated from each other in one direction (e.g., vertical direction in FIG. 3) by the grooves 352 and separated from other conductive sections 350 in another direction (e.g., horizontal direction in FIG. 3) by the grooves 353. In one configuration, each of the grooves 352 that separates the connection element regions 351 in a conductive section 350 are formed in an interleaving pattern, wherein the grooves 352, or separation grooves, are non-straight, non-linear and/or have a wavy pattern, as illustrated in FIGS. 3 and 4. Thus, each of the adjacently positioned connection element regions 351 may have finger regions 351A that are physically and electrically separated from each other by the groove 352. The separation groove 352 may be formed by removing portions of a solid conductive foil material, for example, by use of an automated punch press, abrasive saw, laser scribing device or other similar cutting technique. In one configuration, each of the connection element regions 351 is formed in a separate formation process and then positioned in a spaced apart relationship on the backsheet 203 so that the groove 352 electrically separates each connection element region 351. In one configuration, the solar cells 201 are back contact solar cells that have a first electrical polarity (e.g., p-type active regions (e.g., active region 202B in FIG. 2)) that is positioned in electrical contact with the finger regions 351A of the connection element region 351 on one side of the groove 352, while a back contact of the same solar cell 201 having an opposite electrical polarity (e.g., n-type active regions (e.g., active region 202A in FIG. 2)) is positioned in electrical contact with the finger regions 351A of the connection element region 351 on the opposite side of the groove 352. Thus, when used in a photovoltaic module that has a plurality of solar cells that are connected in series, the finger regions 351A of the connection element regions 351 are used to connect regions formed in adjacent solar cells that have an opposing dopant types. In one example, each conductive sections 350, containing connection element regions 351, is used to interconnect a group of solar cells 201, such as the four solar cells disposed in one of the four solar cell columns over the conductive sections 350 in the photovoltaic module 200 illustrated in FIG. 3.

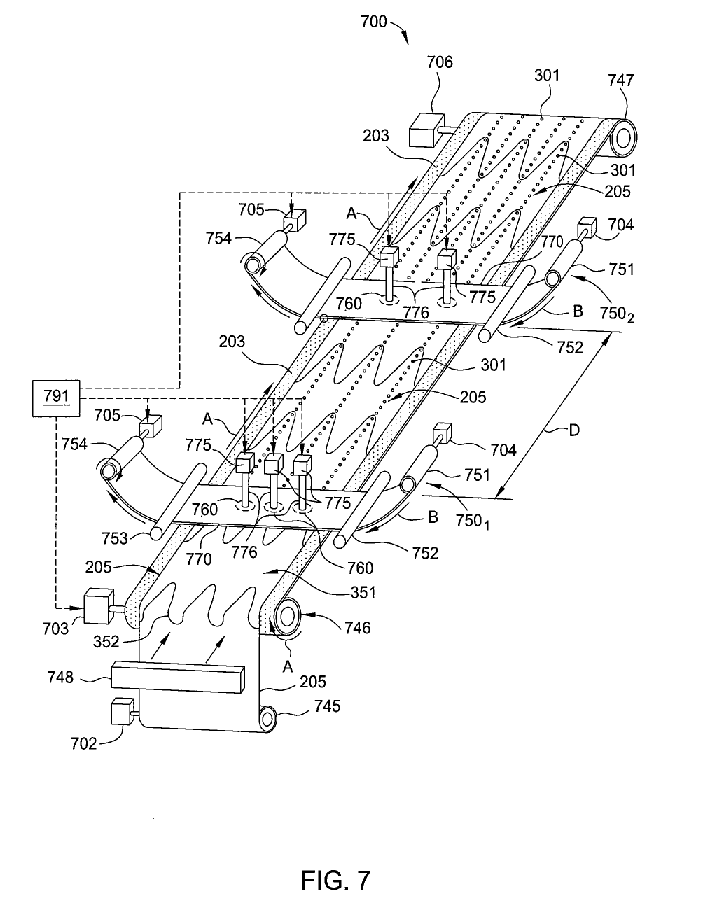

The conductive element 205 will generally comprise a sectioned thin inexpensive metal foil material that has a thickness 206 (FIG. 2) that is between about 25 and 200 μm thick, such as about 75 μm thick. In one example, the thickness 206 of the conductive element 205 is less than about 200 μm. In another example, the thickness 206 of the conductive element 205 is less than about 125 μm. In one embodiment, conductive element 205 comprises an aluminum (Al) containing material, such as a 1000 series aluminum material (Aluminum Association designation). In some embodiments, the conductive element 205 may comprise nickel, titanium, or other useful conductive material. In one example, the conductive element 205 comprises a 50 μm thick sheet of 1145 aluminum that has a plurality of separation grooves cut therein to form connection element regions 351 disposed in the photovoltaic module 200. In some cases, the conductive element 205 is cut into a desired shape and/or pattern from a continuous roll of material, as discussed below in conjunction with FIG. 7.

In one embodiment, the solar cells 201 are positioned over the connection element regions 351 of the sectioned conductive element 205, and are electrically connected to the connection element regions 351 by use of the patterned conductive interconnect material 210. In one configuration, the solar cells 201 are positioned so that the patterned conductive interconnect material 210 is aligned with the solar cell's bond pads and the desired connection element regions 351. In one example, the solar cell bond pads are coupled to active regions 202A or 202B (FIG. 2) formed on the rear surface of a back-contact solar cell device. In this example, the active region 202A is an n-type region formed in a first solar cell and the active region 202B is a p-type region formed in a second solar cell, which are connected together by a connection element region 351. One skilled in the art will appreciate that the orientation of the n-type and p-type regions illustrated FIG. 2 are not intended to be limiting, since the orientation or position of these regions could be rearranged without deviating from the basic scope of the invention described herein. In general, the active regions of the solar cell 201 are portions of the formed solar cell 201 through which at least a portion of the generated current will flow when the solar cell 201 is exposed to sunlight. The conductive interconnect material 210 can be an electrically conductive adhesive (ECA) material, such as a metal filled epoxy, metal filled silicone or other similar polymeric material that has a conductivity that is high enough to conduct the electricity generated by the formed solar cell 201. In one example, the conductive interconnect material 210 has a resistivity that is less than about 1×10⁻⁵ ohm-centimeters. During the photovoltaic module formation process the conductive interconnect material 210 may be positioned in vias 209 formed in the interlayer dielectric layer (ILD) material 208 and module encapsulant material 211 (e.g., EVA material) using a screen printing, ink jet printing, ball application, syringe dispense or other useful application method. One skilled in the art will appreciate that the use of an ECA material to interconnect the solar cells 201 and the connection element regions 351 is not intending to be limiting as to the scope of the invention described herein, since various soldering or other similar electrical connection techniques could be used to form an electrical connection between the solar cells 201 and the connection element regions 351, which use other types of conductive material (e.g., solder materials: Pb, Sn, Bi or alloys thereof), without deviating from the basic scope of the invention described herein.

The backsheet 203 may comprises a 100-200 μm thick polymeric material, such as polyethylene terephthalate (PET), polyvinyl fluoride (PVF), polyester, Mylar, kapton or polyethylene. In one example, the backsheet 203 is a 125-175 μm thick sheet of polyethylene terephthalate (PET). In another embodiment, the backsheet 203 comprises one or more layers of material that may include polymeric materials and metals (e.g., 9-50 μm layer of aluminum). In one example, the backsheet 203 comprises a 150 μm polyethylene terephthalate (PET) sheet, a 25 μm thick sheet of polyvinyl fluoride that is purchased under the trade name DuPont 2111 Tedlar™, and a thin aluminum layer (e.g., 25 μm layer of aluminum) deposited on a side of the backsheet 203 opposite to which the conductive element 205 is disposed. It should be noted that the lower surface 203B of the backsheet 203 will generally face the environment, and thus portions of the backsheet 203 may be configured to act as a UV and/or vapor barrier. The backsheet 203 materials are generally selected for its excellent mechanical properties and ability to maintain its properties under long term exposure to UV radiation. The backsheet, as a whole, is preferably certified to meet the IEC and UL requirements for use in a photovoltaic module.

### Contact Region Formation Process(es)

As briefly discussed above, in one embodiment of the invention, a plurality of patterned electrical contact regions 301 are formed on a surface of the connection element regions 351 disposed on the conductive element 205 to reduce the contact resistance created at the interface between each of the patterned conductive interconnect material 210 and the surface of the conductive element 205. Embodiments of the invention generally include methods of processing the conductive element 205 to form the patterned conductive regions 301 thereon to prevent a thick insulating layer, such as an oxide layer, or surface contamination from affecting the effective transfer of current within and out of the photovoltaic module 200.

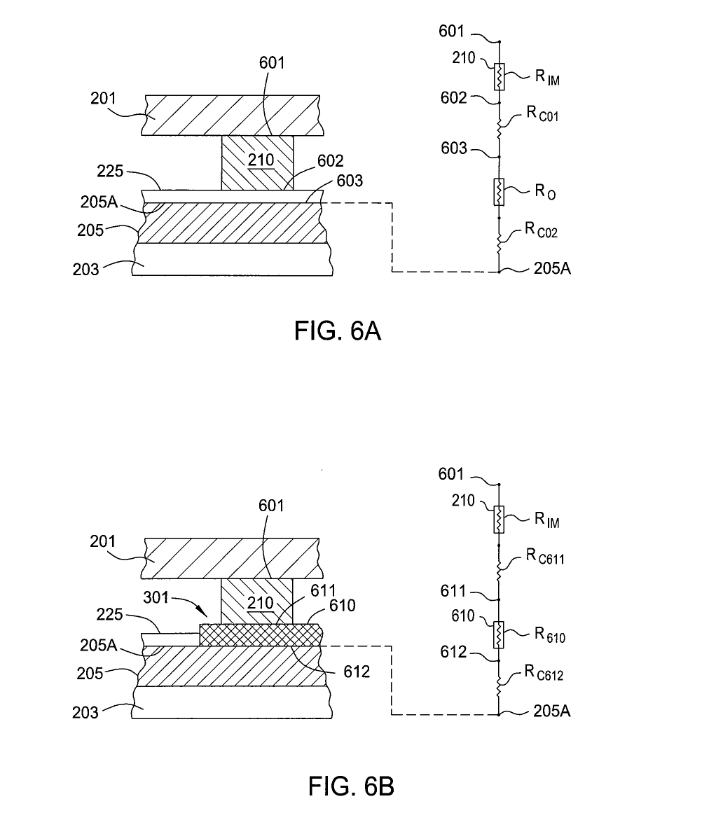

Referring to FIGS. 2-5, in one embodiment of the photovoltaic module 200, each of the conductive sections 350 comprise an inexpensive conductive material, such as an aluminum metal foil, that has a plurality of discrete contact regions 301 formed thereon. The contact regions 301 are generally formed in a desired pattern on the surface of the conductive element 205, coincide with the formed vias 209 formed in the insulating elements (e.g., reference numerals 208 and 211) disposed between the solar cells 201 and the conductive element 205. The contact regions 301 may be formed by simply cleaning regions of the surface of conductive element 205, but is typically formed by depositing and/or bonding a conductive material 610 (FIG. 6B) on regions of the surface of the conductive element 205. FIG. 4 illustrates a portion of a conductive section 350 having a plurality of contact regions 301 formed on the surface 205A of the conductive element 205. FIG. 5 is a close up view of a region of the surface 205A of the conductive element 205 illustrating one possible pattern of the contact regions 301 relative to the finger regions 351A of the connection element regions 351 and the separation grooves 352, and are formed in a pattern that aligns with the electrical connection terminals on a formed solar cell device (not shown) so that they can be electrically connected thereto. In one example, the contact regions 301 disposed on the surface of the conductive element 205 are between about 2 and 10 mm in diameter, such as 6 mm in diameter.

FIG. 6A is a schematic cross-sectional view of a conventional type of electrical connection in which the conductive interconnect material 210 is undesirably positioned on a surface of a conductive element 205 that has a dielectric layer 225, such as a native oxide layer, formed thereon. As shown in FIG. 6A, schematically the current flow path extending from the surface 601 of the solar cell 201 to the surface 612 of the conducting element 205 will electrically consist of the resistance of the electrically conductive materials, such as conductive interconnect material 210 (R_{IM}), the contact resistance formed at the at the surface 602 of the dielectric layer 225 and conductive interconnect material 210, or interface resistance (R_{C01}), the resistance to current flow through the dielectric layer 225 (R₀) and the contact resistance formed of the surface 603 of the dielectric layer 225 and the conductive element 205, or interface resistance (R_{C02}). In one example, due to the typical uncontrolled growth of the native oxide layer found in the dielectric layer 225 the associated resistances, such as R_{C01}, R₀, R_{C02}, will tend to large, such as about 10⁹ ohms for a 5 nm thick layer, due to the thick aluminum oxide layer formed on an 1145 aluminum containing conductive element 205.

FIG. 6B is a schematic cross-sectional view of a conductive interconnect material 210 that is desirably positioned between a solar cell 201 and a conductive element 205 that has a contact region 301 formed there between. In this configuration, the conductive interconnect material 210 is disposed on a surface 711 of the formed contact region 301, which is bonded to conductive element 205. In one embodiment, the contact region 301 is formed so that the dielectric layer 225, such as a native oxide layer, formed on the surface of the conductive element 205 is not in the current path connecting the solar cell 201 and the conductive element 205. In one example, the contact region 301 includes a conductive material 610 that is bonded to the surface of the conductive element 205. Therefore, as shown in FIG. 6B, schematically the current flow path extending from the surface of the solar cell 201 to the surface of the conducting element 205 will electrically consist of the resistance of the electrically conductive materials 110 (R_{IM}), the contact resistance at the conductive material 610 and conductive interconnect material 210 interface (R_{C611}), the resistance to current flow through the conductive material 610 (R₆₁₀) and the contact resistance at the conductive material 610 and conductive element 205 interface (R_{C612}). The contact resistances, such as resistances R_{C611}, R_{C612}, formed in the current flow path will generally be negligible due to the formation of a metallurgical bond at the surface 612 interface during the contact region 301 formation process, and the proper selection of a material that will reliably form a good electrical contact to the conductive interconnect material 210 at the surface 611 interface, which are discussed further below. Moreover, by the selection and use of a conductive material 610 that has a low electrical resistivity (e.g., copper ˜2 μohm-cm) the resistance R₆₁₀, which inhibits current flow through the conductive material 610, will also be negligible as compared to the electrical resistance (R₀) created by passing current through the dielectric layer 225 (e.g., 10¹² ohm difference). In one example, it is desirable to form the contact regions 301 on each connection element region 351 so that the average formed resistance through each contact region 301 is less than about 2×10⁻³ ohms, where the formed resistance for each contact region 301 is equal to the sum of the contact region resistances (i.e., R_{formed}=R_{C611}+R₆₁₀+R_{C612}). However, in some configurations, the bond formed between the portion of the material in the metal sheet and the portion of the material in the conductive element may only need to have a resistance of less than about 4×10⁻³ ohms. In another example, the average resistance for the stack of current carrying elements disposed between the connection points on the solar cell 201 and the surface of the conductive element 205 is less than about 5×10⁻³ ohms, where the stack resistance for each contact region 301 is equal to the sum of the resistance of the current carrying elements (i.e., R_{stack}=R_{CIM}+R_{IM}+R_{C611}+R₆₁₀+R_{C612}, where R_{CIM} (not shown) is the contact resistance at the conductive interconnect material 210 and solar cell 201 contact interface). In yet another example, the average resistance for the stack of current carrying elements disposed between the connection points on the solar cell 201 and the surface of the conductive element 205 is less than about 3×10⁻³ ohms, and the average formed resistance through each contact region 301 is less than about 2×10⁻³ ohms.

In one configuration, the contact regions 301 are formed by depositing a conductive ink or conductive paste in a desired pattern on various regions of the conductive element 205. For example, each of the contact regions 301 are formed by depositing a liquid, paste, or other similar material comprising a metal, such as copper, nickel, chromium, gold, silver, tin, zinc, or alloys thereof, on various region of the surface of the conductive element 205. The liquid, paste or other similar material may be deposited by use of a screen printing, ink jet printing, rubber stamping, vapor depositing through a mask, or other similar technique. In one example, the conductive ink or conductive paste contains copper or nickel. In one configuration, the liquid, paste, or other similar material may also comprise a material that can chemically reduce, etch and/or react with an unwanted layer previously formed on the surface of the conductive element 205 to clean the surface and allow the other material(s) in the liquid or paste to better bond to and/or interact with the surface of the conductive element 205. In one example, the liquid, paste, or other similar material comprises a cleaning material selected from the group comprising activated fluorides (e.g., ammonium fluoride (NH₄F)). In some cases, it may be desirable to provide heat to the deposited liquid, paste, or other similar material to enhance the reaction and/or bonding of the materials in the conductive ink or conductive paste to the surface of the conductive element 205. In one example, a conductive paste comprising between about 1 and about 1000 μm diameter copper particles is heated to a temperature between about 150° C. and about 400° C. to form the contact regions 301.

In another configuration, the contact regions 301 are formed by bonding portions of a metal foil or sheet to the surface of the conductive element 205. In general, the metal foil material will comprise a good electrical contact material, such as copper, nickel, chromium, gold, silver, tin, zinc, or alloys thereof. In one example, each of the contact regions 301 are formed by joining a foil material comprising a metal to various region of the surface of the substrate. The foil material may be joined to the conductive element 205 by use of an ultrasonic welding, spot welding, friction welding, laser welding, ion beam welding, electron beam welding, or other similar joining technique.

### Conductive Element and Backsheet Formation Process(es)

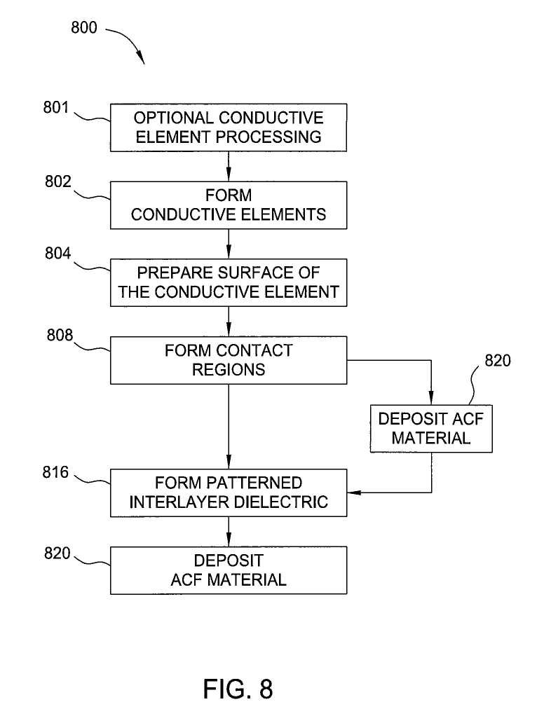

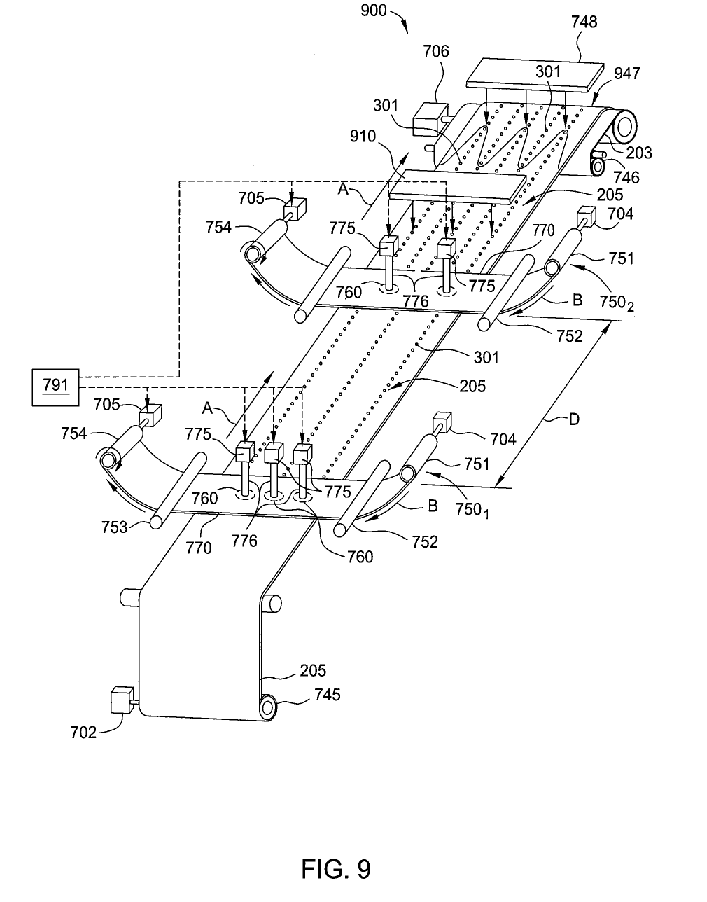

FIGS. 7 and 8 Illustrate an automated system and processing sequence that can be used to form at least part of a photovoltaic module 200 discussed above. FIG. 7 is an isometric view of a system 700 for forming flexible substrates having a plurality of contact regions 301 formed thereon according to one embodiment of the invention. FIG. 8 illustrates a processing sequence 800 used to form the backsheet assembly 230 that is used in a photovoltaic module. The system 700 includes a backsheet feed roll 746, a conductive element feed roll 745, an optional take-up roll 747, and one or more contact region formation devices 750 (e.g., reference numbers 750₁ or 750₂ in FIGS. 7 and 9) disposed over a surface of the conductive element 205. In one embodiment, the system 700 includes a system controller 791 that is used to control the movement of the conductive element 205 between the feed roll 745 and the optional take-up roll 747 by use of conventional rotational actuators 702, 703 and/or 706, and the contact region 301 formation processes performed by the contact region formation device 750. The system 700 and system controller 791 are used to form a plurality of contact regions 301 on the surface of the conductive element 205 in an automated and sequential fashion. The system controller 791 facilitates the control and automation of the overall system 700 and may include a central processing unit (CPU) (not shown), memory (not shown), and support circuits (or I/O) (not shown). The CPU may be one of any form of computer processors that are used in industrial settings for controlling various chamber processes and hardware (e.g., backsheet positioning components, motors, cutting tools, robots, fluid delivery hardware, etc.) and monitor the system and chamber processes (e.g., backsheet position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 791 determines which tasks are performable in the system 700. Preferably, the program is software readable by the system controller 791, which includes code to generate, execute and store at least the process recipes, the sequence of movement of the various controlled components, and any combination thereof, performed during a process sequence.

Referring to FIG. 8, in one embodiment, the processing sequence 800 starts at step 801, in which the surface 205A of the conductive element 205 is processed to roughen the various regions of the surface 205A to allow a desirable bond to form between a subsequently deposited interlayer dielectric material 208 (Step 816) and the surface 205A. In one example, during step 801, a wet cleaning process is performed to etch and prepare the surface 205A of the conductive element 205. Typical wet cleaning processes may include immersing or spraying the surface 205A with chemicals (e.g., acids or bases) that can texture etch the material of the conductive element 205 and/or remove any surface contamination disposed thereon.

In step 802, in which the conductive element 205 material is bonded to a portion of the backsheet 203 fed from the backsheet feed roll 746. The bonding process may include inserting an adhesive material 204 between the backsheet 203 and the conductive element 205, as discussed above. In one embodiment, the bonding process also includes forming the connection element regions 351 in an un-sectioned portion of the conductive element 205 material, which is fed from the conductive element feed roll 745. The connection element regions 351 may be created by forming the separation grooves 352 and/or 353 by removing portions of the conductive element 205 material by use of an automated cutting device 748 (e.g., punch press, abrasive saw, laser scribing device) that is controlled by the system controller 791. It should be noted that, in one embodiment, step 801 may be performed after the processes performed during step 802 have been performed on the conductive element 205.

Next at step 804, the surface 205A of the conductive element 205 is optionally prepared so that contact regions 301 that have good electrical characteristics can be reliably formed on the conductive element 205. In one example, during step 804, a wet cleaning process is performed to remove any contamination found on the surface 205A of the conductive element 205. Typical wet cleaning processes may include immersing or spraying the surface 205A with DI water and/or chemicals that can etch and remove the native oxide layer and/or other surface contamination. In another example, during step 804, a dry cleaning process, such as a RF plasma clean process is performed to remove any contamination found on the surface 205A of the conductive element 205. Typical dry cleaning processes may include, disposing a portion of the surface 205A of the conductive element 205 in a sub-atmospheric pressure environment and then exposing the surface 205A to an RF or DC plasma that contains an inert and/or reactive gas (e.g., NF₃) to sputter etch and remove the native oxide layer and/or other surface contamination.

Next at step 808, a plurality of contact regions 301 are formed on the surface 205A of the conductive element 205, for example by use of the system 700. In one configuration of the system 700, a contact region formation device 750 is used to form the contact regions 301 on the surface 205A by bonding portions of a metal foil or sheet to the surface 205A, as discussed above. In one configuration, the contact region formation device 750 includes a deposition material 770 that is disposed between a material feed roll 751 and a take-up roll 754, and one or more deposition devices 775 that are configured to form the contact regions 301 on the surface of the conductive element 205. In one example, the deposition is a sheet of a conductive material (e.g., Cu, Ni, Sn) that is between about 0.5 and 200 μm thick. In one embodiment, contact region formation device 750 includes one or more guide rollers 752, 753 and one or more actuators 704 and/or 705 (e.g., electric motor(s)) that are used to position the deposition material 770 over a desired portion of the conductive element 205 (e.g., direction “B”) to enable the one or more deposition devices 775 to join portions of the deposition material 770 on portions of the conductive element 205.

In one configuration of the system 700, the one or more deposition devices 775 each comprise an ultrasonic energy application device that are configured to deliver energy to portions the deposition material 770 and portions of the conductive element 205 to form a metallurgical bond between portions of the deposition material 770 and the base material of the conductive element 205. In one example of a contact region formation process, the one or more deposition devices 775 apply high-frequency ultrasonic vibrations locally to regions 760 of the deposition material 770 and regions of the conductive element 205, which are at least momentarily held together under pressure by the energy applicator 776 of each of the deposition devices 775, to create the solid-state metallurgical bond within the local regions 760. The local regions 760 of the deposition material 770 may be precut to allow easy separation from the deposition material 770 after forming the metallurgical bond, or be sectioned from the deposition material 770 after the metallurgical bond is formed by use of a knife, punch, scribing devices or scanned laser.

In one embodiment, the system 700 includes two or more contact region formation devices, such as contact region formation devices 750₁ and 750₂ illustrated in FIG. 7, that are spaced a desired distance apart along the conductive element feed direction “A” so that multiple groups of contact regions 301 can be formed over different regions of the conductive element 205 at one time. This automated configuration can be advantageous where high speed formation of many contact regions 301 is needed, since it will allow the formation of multiple contact regions 301 on different regions of the surface 205A to be formed sequentially. One will note that FIG. 7 illustrates a configuration in which the contact regions 301 are formed by two separate contact region formation devices 750₁, 750₂ that are configured to form adjacent columns of contact regions 301 (e.g., parallel to the feed direction “A”). In some embodiments, the two or more contact region formation devices are configured to form adjacent rows (e.g., perpendicular to the feed direction “A”) of contact regions 301 that are formed by indexing the conductive element 205 an amount that is a multiple of the spacing, or distance “D”, between the contact region formation devices 750. In one example, the contact region formation devices 750 are spaced a distance “D” apart and thus the conductive element 205 may be indexed a distance Z, which is equal to the distance “D” divided by X (i.e., Z=D/X), where X is a number that is less than, equal to or greater than one, to sequentially form the contact regions 301 on the surface 205A of the conductive element 205.

In another configuration of the system 700, during step 808, a contact region formation device 750 is used to form the contact regions 301 by depositing a conductive ink or conductive paste on the surface 205A of the conductive element 205 that is then further processed to form the contact regions 301. In one configuration, the contact region formation device 750 includes one or more deposition devices 775 that are configured to deposit the conductive ink, or conductive paste, on the surface of the conductive element 205, as discussed above. In one embodiment, contact region formation device 750 is a screen printing, ink jet printing, rubber stamping, vapor depositing through a mask, or other similar technique that is configured to deposit a liquid, paste, or other similar material comprising a metal, such as copper, nickel, chromium, gold, silver, tin, zinc, or alloys thereof to form the contact regions 301 on the surface of the conductive element 205. The conductive ink, or conductive paste, may then be heated to a desired temperature to cause the material(s) in the conductive ink, or conductive paste, to form a metallurgical bond with the base material of the conductive element 205. In one example of a contact region formation process, the one or more deposition devices 775 are adapted to deliver an organic binder containing copper powder paste that is deposited on the surface of the conductive element 205. The copper powder may comprise a pure copper powder, a silver coated copper powder, tin coated copper powder, other solderable metal coated copper powders or combination thereof. The deposited paste is then heated by lamps to a temperature (e.g., ˜150-400° C.) high enough to cause the copper powered to alloy with the conductive element 205 material (e.g., Al) and/or sinter to form a copper layer that has a metallurgical bond within the conductive element 205 material. In one configuration, the post deposition heating process may include heating the conductive ink, or conductive paste, which is disposed on a portion of the conductive element 205, to a desired temperature while the portion of the conductive element 205 is disposed in an inert gas containing (e.g., nitrogen (N₂)) and/or reducing gas containing (e.g., hydrogen (H₂)) environment.

In step 816, a interlayer dielectric (ILD) material is printed on the surface 205A using a dielectric application device (not shown), such as a screen printing device, stenciling device, ink jet printing device, rubber stamping device or other useful application device. The interlayer dielectric is applied in a pattern substantially covering the surface 205A; however, openings 219 are left therethrough to allow for electrical connections to be made between the surface 205A and a solar cell 201 subsequently positioned over the surface 205A. In one embodiment, the interlayer dielectric (ILD) material 208 is a UV curable material, such as an acrylate resins, methacrylate resins, acrylic or phenolic polymer materials. In one embodiment, the interlayer dielectric (ILD) material 208 is deposited to form a thin layer that is between about 10 and 25 μm thick over portions of the surface 205A that are not covered by the contact regions 301.

In step 820, a layer of an anti-corrosion finish (ACF) material is optionally positioned on the contact regions 301, which are not covered by the interlayer dielectric, to prevent oxidation of the exposed areas of the contact regions 301. In one example, the anti-corrosion finish material may be selected from one of the classes of desirable contact enhancing materials known as organic solderability preservative (OSP) materials or silver immersion finish materials. In one example, the OSP material may be a tarnish inhibitor, such as ENTEK® CU 56 available from Enthone, Inc. that is deposited by use of an immersion coating or other similar technique. In another example, the ACF comprises a silver immersion material that has a thickness between about 0.5 and about 6 μm, such as 1 μm over the surface of the contact region 301. As illustrated in FIG. 8, in some alternate configurations it is desirable to deposit the ACF material over the contact regions 301 just after forming the contact regions in step 808 and before performing step 812. In other configurations, it may be desirable to deposit the ACF material over the contact regions 301 just after performing step 812 and before performing step 816.

After performing processing steps 802-820 the backsheet assembly 230 may be stored for processing at some later time, or the photovoltaic module formation process may continue by then depositing the conductive interconnect material 210 on the surface of the contact regions 301 that is found in the bottom of the vias 209 (FIG. 2) formed in the ILD material 208 disposed over the surface 205A. The conductive interconnect material 210 may be deposited by a screen printing, ink jet printing, or other similar technique. In the next part of the process, the module encapsulant material 211, plurality of solar cells 201, front encapsulant layer 215 and glass substrate 216 are positioned over the surface 205A of a portion of the conductive element 205 sectioned from the feed roll 745 to allow each of the solar cells 201 to be electrically connected to the surface 205A of the connection element regions 351 through the deposited conductive interconnect material 210. After connecting the solar cells 201, a lamination process is typically performed to hermetically seal the solar cells 201 in a region formed between the backsheet 203 and the glass substrate 216. In one embodiment, the lamination process causes the encapsulant material 211 to soften, flow and bond to all surfaces within the photovoltaic module 200, and the adhesive material 204 and conductive interconnect material 210 to cure in a single processing step. The lamination processing step generally applies pressure and temperature to the assembly, such as the glass substrate 216, encapsulant material 211, solar cells 201, conductive interconnect material 210, conductive element 205, adhesive material 204 and backsheet 203, while a vacuum pressure is maintained around the stacked assembly. In one example of a lamination process, a flexible blanket is configured to apply pressure of about one atmosphere (e.g., 0.101 MPa) to the assembly as it is heated to a temperature of between about 150° C. and about 165° C., while the processing environment inside the blanket, and surrounding the photovoltaic module assembly, is maintained at a vacuum pressure (e.g., ˜100-700 Torr).

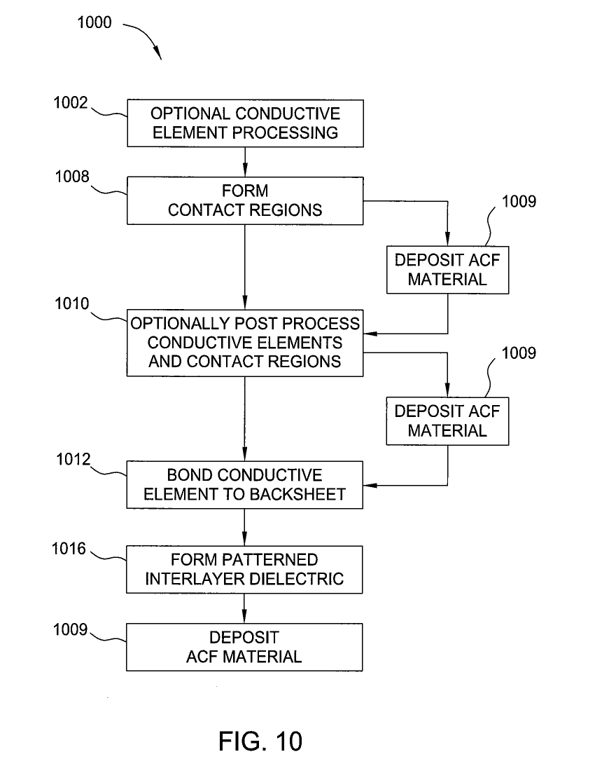

FIG. 9 is an isometric view of a system 900 that can be used to form a plurality of contact regions 301 on a conductive element 205 that is used to form a part of a flexible substrate according to one embodiment of the invention. FIG. 10 illustrates a processing sequence 1000 used to form the backsheet assembly 230 that is used in a photovoltaic module. In some configurations, system 900 is similar to the system 700, and thus the components illustrated in FIG. 9 that have similar reference numerals to the components found in FIG. 7 will generally not be re-discussed below. The system 900 generally includes a conductive element feed roll 745, an optional conductive element take-up roll 947, one or more contact region formation devices 750 disposed over a surface of the conductive element 205, and an optional processing device 910. In one embodiment, the system 900 includes a system controller 791 that is used to control the movement of the conductive element 205 between the conductive element feed roll 745 and the optional conductive element take-up roll 947 by use of conventional rotational actuators 702 and/or 706, the contact region 301 formation processes performed by the one or more contact region formation devices 750 and any subsequent contact region 301 processing steps. The system 900 and system controller 791 are used to form and prepare a plurality of contact regions 301 on the surface of the conductive element 205 in an automated and sequential fashion.

The configuration of system 900 can be desirable, since it allows the contact regions 301 to be formed on the conductive element 205 and the conductive element 205 and contact regions 301 to be further processed without the backsheet 203 or adhesive material 204 being damaged by one or more of the contact region formation and/or further processing steps. The processed conductive element 205 can then be bonded to the backsheet 203 during one of the subsequent processing steps. In one configuration, the additional processing steps applied to the contact regions 301 formed on the conductive element 205 include exposing the conductive element 205 and contact regions 301 to an amount of energy from the processing device 910 to heat at least a portion of the conductive element 205 on which the contact regions 301 are formed. In one example, the processing device 910 is a radiant heat lamp, IR heater, laser or other similar device that is adapted to deliver energy to at least a portion of the conductive element 205 disposed between the feed roll 745 and the optional conductive element take-up roll 947.

Referring to FIG. 10, in one embodiment, the processing sequence 1000 starts at step 1002, in which the surface 205A of the conductive element 205 is processed to roughen the various regions of the surface 205A to allow a desirable bond to form between a subsequently deposited interlayer dielectric (ILD) material 208 (Step 1016) and the surface 205A of the conductive element 205. In one example, during step 1002, a wet cleaning process is performed to etch and prepare the surface 205A of the conductive element 205. Typical wet cleaning processes may include immersing or spraying the surface 205A with chemicals (e.g., acids or bases) that can texture etch and/or remove surface contamination disposed thereon. During step 1002, the surface 205A of the conductive element 205 is also optionally prepared so that the contact regions 301, which have good electrical characteristics, are reliably formed on the conductive element 205. In one example, during step 1002, a wet cleaning process is performed to remove any contamination found on the surface 205A of the conductive element 205. Typical wet cleaning processes may include immersing or spraying the surface 205A with DI water and/or chemicals that can etch and remove the native oxide layer and/or other surface contamination. In another example, during step 1002, a dry cleaning process, such as an RF plasma clean process is performed to remove any contamination found on the surface 205A of the conductive element 205.

Next at step 1008, a plurality of contact regions 301 are formed on the surface 205A of the conductive element 205, for example by use of the system 900. In one configuration of the system 900, a contact region formation device 750₁, 750₂ is used to form the contact regions 301 on the surface 205A by bonding portions of a metal foil or sheet to the surface 205A, as discussed above in conjunction with FIGS. 7 and 8. In one example, the deposition is a sheet of a conductive material (e.g., Cu, Ni, Sn) that is between about 0.5 and 200 μm thick. The system 900 may also include two or more contact region formation devices 750, such as contact region formation devices 750₁ and 750₂, as illustrated in FIG. 9, so that multiple groups of contact regions 301 can be formed over different regions of the conductive element 205 at one time, as discussed above in conjunction with FIGS. 7 and 8. This automated configuration can be advantageous where high speed formation of many contact regions 301 is needed, since it will allow the formation of multiple contact regions 301 on different regions of the surface 205A to be formed sequentially. In one configuration of the system 900, as discussed above, the one or more deposition devices 775 each comprise an ultrasonic energy application device that are configured to deliver energy to portions the deposition material 770 and portions of the conductive element 205 to form a metallurgical bond between portions of the deposition material 770 and the base material of the conductive element 205.

In another configuration of the system 900, during step 1008, a contact region formation device 750 is used to form the contact regions 301 by depositing a conductive ink or conductive paste on the surface 205A of the conductive element 205 that is then further processed to form the contact regions 301. In one configuration, the contact region formation device 750 includes one or more deposition devices 775 that are configured to deposit a conductive ink, or conductive paste, on the surface of the conductive element 205, as discussed above in conjunction with FIGS. 7 and 8. The conductive ink, or conductive paste, may then be heated during processing step 1010 to cause the material(s) in the conductive ink, or conductive paste, to form a metallurgical bond with the base material of the conductive element 205 by use of the processing device 910.

In step 1009, a layer of an anti-corrosion finish (ACF) material is optionally positioned on the contact regions 301 to prevent oxidation of the exposed areas of the contact regions 301, as discussed above in conjunction with step 820. As illustrated in FIG. 10, in some alternate configurations it is desirable to deposit the ACF material over the contact regions 301 just after forming the ILD material 208 in step 1016.

In step 1010, the conductive element 205 and contact regions 301 are then optionally post processed to enhance the physical or electrical properties of the conductive element 205 and/or the contact regions 301. In one example, as discussed above, the processing device 910 is adapted to deliver an amount of energy to a portion of the conductive element 205 and the contact regions 301 to anneal, sinter, or heat treat the deposited conductive material 610 to improve its bond to the conductive element 205, and/or the physical and/or electrical properties of at least the surface 611 of the contact region 301. In another example of the processing sequence 1000, the post deposition heating process includes heating the conductive ink, conductive paste, or portions of the deposition material 770, which are disposed on a portion of the conductive element 205, to a desired temperature while the portion of the conductive element 205 is disposed in an inert gas containing (e.g., nitrogen (N₂)) and/or reducing gas containing (e.g., hydrogen (H₂)) environment. In one configuration of the system 900 and processing sequence 1000, the processing device 910 may alternately, or also, contain components that are used to clean the surface of the conductive element 205 and/or the contact regions 301 by use of a wet or dry cleaning process as discussed above (e.g., step 804). It should be noted that in some configurations of the processing sequence 1000, it may be desirable to perform step 1010 before completing step 1009, since the post processing steps may undesirably alter physical or electrical characteristics of the deposited ACF material.

In step 1012, the conductive element 205 with contact regions 301 formed thereon is then bonded to a portion of the backsheet 203 fed from the backsheet feed roll 746. The bonding process may include inserting an adhesive material 204 between the backsheet 203 and the conductive element 205, as discussed above. In one embodiment, the bonding process also includes forming the connection element regions 351 in an un-sectioned portion of the conductive element 205 material, which is fed from the conductive element feed roll 745. The connection element regions 351 may be created by forming the separation grooves 352 and/or 353 by removing portions of the conductive element 205 material by use of an automated cutting device 748 (e.g., punch press, abrasive saw, laser scribing device) that is controlled by the system controller 791.

In step 1016, a patterned interlayer dielectric (ILD) material 208 is printed on the surface 205A using a dielectric application device (not shown), such as a screen printing device, stenciling device, ink jet printing device, rubber stamping device or other useful application device, as discussed above in conjunction with FIGS. 7 and 8. The interlayer dielectric is applied in a pattern substantially covering the surface 205A; however, openings 219 are left therethrough to allow for electrical connections to be made between the surface 205A and a solar cell 201 subsequently positioned over the surface 205A.

It should be noted that steps 1008-1016 need not be done in a consecutive or serial manner, as illustrated in FIG. 10, and thus may be performed at different times or in different fabrication locations. For example, in one configuration of processing sequence 1000, after performing steps 1002-1010 the conductive element 205 is wound on to a roll and stored for a period of time, and/or transported to another location, at which time it is unrolled and joined to the backsheet 203 by performing the process(es) found in step 1012. In another example of the processing sequence 1000, the process steps 1002-1010 and step 1016 are performed on a conductive element 205 that is then wound on to a roll and stored for a period of time, and/or transported to another location. After storing and/or transporting the processed conductive element 205, it is then joined to the backsheet 203 by performing the process(es) found in step 1012.

After performing processing steps 1002-1016 the backsheet assembly 230 may be stored for processing at some later time, or the photovoltaic module formation process may continue by then depositing the conductive interconnect material 210 on the surface of the contact regions 301 that is found in the bottom of the vias 209 (FIG. 2) formed in the ILD material 208 disposed over the surface 205A. In the next part of the process, the module encapsulant material 211, plurality of solar cells 201, front encapsulant layer 215 and glass substrate 216 are positioned over the surface 205A of a portion of the conductive element 205 sectioned from the feed roll 745 to allow each of the solar cells 201 to be electrically connected to the surface 205A of the connection element regions 351 through the deposited conductive interconnect material 210. After connecting the solar cells 201, a lamination process is typically performed to hermetically seal the solar cells 201 in a region formed between the backsheet 203 and the glass substrate 216, as discussed above.

In one embodiment of processing sequence 800 or 1000, the system 700 or 900 is configured to form contact regions 301 on a conductive element 205 which is then subsequently sectioned into two or more conductive sections 350 for use in one or more photovoltaic modules 200. In one example, the conductive element 205 is sectioned into between about 2 and about 10 conductive sections 350, which are then used in a single photovoltaic module 200. In one configuration, the conductive element 205 is bonded to the backsheet 203, and then sectioned to form a plurality of conductive sections 350 that are supported by the backsheet 203.

While the foregoing is directed to embodiments of the present invention, other and further embodiments of the invention may be devised without departing from the basic scope thereof, and the scope thereof is determined by the claims that follow.

We claim:

1. A substrate for interconnecting photovoltaic devices, comprising:
a flexible backsheet;
a conductive element comprising aluminum that is disposed over a first surface of the flexible backsheet, wherein the conductive element comprises a plurality of connection element regions that are electrically separated from each other by one or more grooves; and
a plurality of a contact regions disposed on a surface of each of the connection element regions, wherein each of the contact regions comprise a conductive material that is not aluminum.

2. The substrate of claim 1, wherein the contact regions comprise a metal foil that is bonded to the conductive element.

3. The substrate of claim 2, further comprising an anti-corrosion finish layer formed over at least a portion of each of the contact regions.

4. The substrate of claim 1, wherein the conductive material comprises an element selected from a group consisting of copper, nickel, chromium, gold, silver, tin and zinc or combinations thereof.

5. The substrate of claim 1, wherein the flexible backsheet comprises polyethylene terephthalate, polyvinyl fluoride, polyester, mylar, kapton or polyethylene, and the conductive element is between about 25 and 200 μm thick.

6. The method of claim 5, wherein the flexible backsheet further comprises an aluminum layer disposed on a second surface of the flexible backsheet.

7. The substrate of claim 1, further comprising:
an interlayer dielectric layer disposed over at least a portion of each of the conductive element regions, wherein a portion of a surface of each of the contact regions is not covered by the interlayer dielectric layer.

8. The substrate of claim 1, wherein the conductive element further comprises a plurality of conductive sections that are electrically isolated from each other by a first groove, and wherein the one or more grooves of the conductive element comprise a second groove that has a different shape from the first groove.

9. The substrate of claim 1, wherein each of the one or more grooves are configured to form finger regions in adjacent connection element regions, wherein the finger regions formed in each connection element region are configured to connect with active regions of a back contact solar cell that have the same polarity.

10. A substrate for interconnecting photovoltaic devices, comprising:
a flexible backsheet;
a conductive element comprising aluminum that is disposed over a first surface of the flexible backsheet, wherein the conductive element comprises a plurality of connection element regions that are electrically separated from each other by one or more grooves; and
a plurality of a contact regions disposed on a surface of each of the connection element regions, wherein the contact regions comprise a conductive material that comprise copper, silver, tin or zinc.

11. The substrate of claim 10, wherein the contact regions comprise a metal foil that is bonded to the conductive element.

12. The substrate of claim 11, further comprising an anti-corrosion finish layer formed over at least a portion of each of the contact regions.

13. The substrate of claim 10, wherein the flexible backsheet comprises polyethylene terephthalate, polyvinyl fluoride, polyester, mylar, kapton or polyethylene, and the conductive element is between about 25 and 200 μm thick.

14. The method of claim 13, wherein the flexible backsheet further comprises an aluminum layer disposed on a second surface of the flexible backsheet.

15. The substrate of claim 10, further comprising:
an interlayer dielectric layer disposed over at least a portion of each of the conductive element regions, wherein a portion of a surface of each of the contact regions is not covered by the interlayer dielectric layer.

16. The substrate of claim 10, wherein the conductive element further comprises a plurality of conductive sections that are electrically isolated from each other by a first groove, and wherein the one or more grooves of the conductive element comprise a second groove that has a different shape from the first groove.

17. The substrate of claim 10, wherein each of the one or more grooves are configured to form finger regions in adjacent connection element regions, wherein the finger regions formed in each connection element region are configured to connect with active regions of a back contact solar cell that have the same polarity.

18. A method of forming a substrate for interconnecting photovoltaic devices, comprising:
bonding a conductive element to a backsheet, wherein the conductive element comprises a metal layer that has a conductive element surface;
removing a portion of the conductive element to form two or more conductive element regions that are electrically isolated from each other; and
forming plurality of a contact regions on at least a portion of the conductive element surface.

19. The method of claim 18, wherein forming the plurality of contact regions on the conductive element surface further comprises:
disposing a metal sheet over a portion of the conductive element surface; and
delivering energy to at least a portion of the metal sheet and at least a portion of the conductive element surface to cause a bond to form between a portion of the material in the metal sheet and a portion of the material in the conductive element.

20. The method of claim 19, wherein delivering energy further comprises:
delivering ultrasonic energy to the at least a portion of the metal sheet and the at least a portion of the conductive element.

21. The method of claim 18, further comprising forming an anti-corrosion finish layer over at least a portion of each of the contact regions.

22. The method of claim 18, wherein forming the plurality of a contact regions on the surface of the conductive element further comprises:
disposing a material on the surface of the conductive element, wherein the material comprises a metal selected from the group comprising copper, nickel, chromium, gold, silver, tin and zinc or combinations thereof; and
delivering energy to the conductive element and the material to cause the metal to form a bond to the surface of the conductive element.

23. The method of claim 23, further comprising removing an oxide layer from the conductive element surface by exposing the surface to a fluorine containing compound, wherein removing the oxide layer is performed before disposing the material on the surface of the conductive element.
